(19) United States
(12) Patent Application Publication
(10) Pub. No.: US 2003/0180629 A1
(43) Pub. Date: Sep. 25, 2003

(54) Masks and method for contact hole exposure

(75) Inventor: Yuan-Hsun Wu, Jungli City (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/308,746

(22) Filed: Dec. 3, 2002

(30) Foreign Application Priority Data
Mar. 20, 2002 (TW) 91105297

(51) Int. Cl. G03F 1/00; G21K 3/00; G03F 7/20

(52) U.S. Cl. 430/5; 378/35; 430/311

(57) ABSTRACT

A mask and method for contact hole exposure. First, a mask including a transparent substrate, a 180° phase shift layer installed on the transparent substrate to define a series of patterns having contact hole transparent areas with 0° phase, and at least one 0° phase opening installed in the phase shift layer between the adjacent contact hole transparent areas is provided. Then, an exposure is performed by transmitting a light source, such as deep ultraviolet (UV), extreme ultraviolet, or X-ray, through the mask, so as to eliminate high degree diffraction waves by the 0° phase opening.

### BACKGROUND OF THE INVENTION

1. Field of the Invention

The present invention relates in general to semiconductor manufacturing, and particularly to photolithography, ad contact hole exposure processes for the same.

2. Description of the Related Art

In the manufacture of semiconductor wafers, photolithography is used to pattern various layers on a wafer. A layer of resist is deposited on the wafer and exposed using an exposure tool and a template such as a mask. During the exposure process a form of radiant energy such as ultraviolet light is directed through the mask to selectively expose the resist in a desired pattern. The resist is then developed to remove either the exposed portions for a positive resist or the unexposed portions for a negative resist, thereby forming a resist mask on the wafer. The resist mask can then be used to protect underlying areas of the wafer during subsequent fabrication, such as deposition, etching, or ion implantation.

An integral component of photolithography is the mask. The mask includes the pattern corresponding to features (e.g., transistors or polygates) at a layer of the integrated circuit (IC) design. The mask is typically a transparent glass plate coated with a patterned light blocking material such as, for example, Chromium. This type of mask is typically referred to as a binary mask since light is completely blocked by the light blocking material and fully transmitted through the transparent glass portions.

There are problems with the PSM mask. Light passing through the edge of contact hole patterns within the mask (e.g., the boundary between a light blocking region and a transparent region) is oftentimes diffracted. This means that instead of producing a very sharp image of the contact holes on the resist layer, some lower intensity light diffracts beyond the intended contact hole boundary and into the regions expected to remain dark. Hence, the resultant feature shapes and sizes deviate somewhat from the intended IC design. Since integrated circuit manufacturers have continued to reduce the geometric size of the IC features, this diffraction produces wafers with incomplete or erroneous circuit patterns.

FIG. 1 illustrates a portion of a mask 10 for contact hole patterns. The mask 10 comprises a transparent portion 20 that permits transmission of radiant energy, such as ultraviolet light.

FIG. 2 illustrates the printable patterns on a photoresist 30 after an exposure and a development using the mask 10. There are not only a plurality of circular contact holes 40 but also side lobes 50 produced by diffraction among the contact holes 40.

As known in the art, the side lobe effect becomes more pronounced as the spacing between the IC features decreases, especially for contact hole formation. That is, when contact holes are designed close to each other, as in the current trend, the electrical field and intensity components associated with the side lobes of each feature begin to overlap and add up. This causes side lobes of greater amplitude and increases the side lobe effect. Sometimes, the amplitude of these “additive” side lobes is greater than the amplitude of the desired features, which further corrupts the fabrication process.

One way to solve the side lobe problem in photolithography is the application of a phase-shifting mask (PSM). Dummy patterns are designed in a PSM to reduce side lobes by diffraction. However, it is difficult to fabricate the PSM.

Increasing the degree of coherence of the lens is another way to solve the above mentioned side lobe problem. However, the depth of focus (DOF) decreases with the increase. Thus, the process window of photolithography becomes narrow.

### SUMMARY OF THE INVENTION

The object of the present invention is to provide a mask and method for contact hole exposure to avoid side lobe problems.

The method comprises the following steps. First, a mask including a transparent substrate, a 180° phase shift layer installed on the transparent substrate to define a series of patterns having contact hole transparent areas with 0° phase, and at least one 0° phase opening installed in the phase shift layer between the adjacent contact hole transparent areas is provided. Then, an exposure is performed by transmitting a light source, such as deep ultraviolet (UV), extreme ultraviolet, or X-ray, through the mask, so as to eliminate high degree diffraction waves by the 0° phase opening.

The present invention also provides a mask for contact hole exposure. The mask comprises a transparent substrate, a 180° phase shift layer installed on the transparent substrate to define a series of patterns having contact hole transparent areas with 0° phase, and at least one 0° phase opening installed in the phase shift layer between the adjacent contact hole transparent areas to eliminate high degree diffraction waves.

Each of the contact hole transparent areas can be rectangular and about 100˜300 nm. The pitch between the contact hole transparent areas is about 300˜600 nm. As well, the transparent substrate comprises quartz, and the phase shift layer comprises MoSiON.

In the present invention, the 0° opening is installed at the convergence of four adjacent contact hole transparent areas, and is rectangular.

### BRIEF DESCRIPTION OF THE DRAWINGS

The above and other objects, features, and advantages of the present invention will become apparent from the following detailed description of preferred embodiments of the invention explained with reference to the accompanying drawings, in which:

FIG. 1 is a top view schematic drawing showing a mask having contact hole patterns.

FIG. 2 is schematic drawing illustrating the side lobe problem according to the prior art.

FIG. 3 is a top view schematic drawing of the mask according to the preferred embodiment of the invention.

FIG. 4 is a schematic cross-section of the mask according to the preferred embodiment of the invention.

FIG. 5 is a schematic drawing illustrating the method for contact hole exposure according to the preferred embodiment of the invention.

FIG. 6 is a schematic drawing showing photoresist patterns after an exposure and a development by the mask of FIGS. 3 and 4 according to the preferred embodiment of the invention.

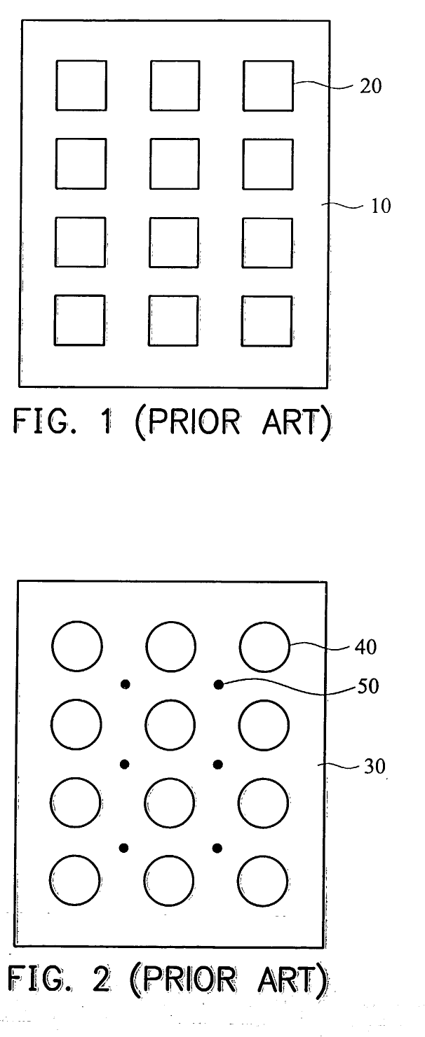

### DETAILED DESCRIPTION OF THE INVENTION

There will now be described an embodiment of this invention with reference to the accompanying drawings.

First, a mask 110 comprises a transparent substrate 300, a 180° phase shift layer 302 installed on the transparent substrate 300 to define a series of patterns having contact hole transparent areas 120 with 0° phase, and at least one 0° phase opening 160 installed in the phase shift layer 302 between the adjacent contact hole transparent areas 120 is provided. The contact hole transparent areas 120 are set in array.

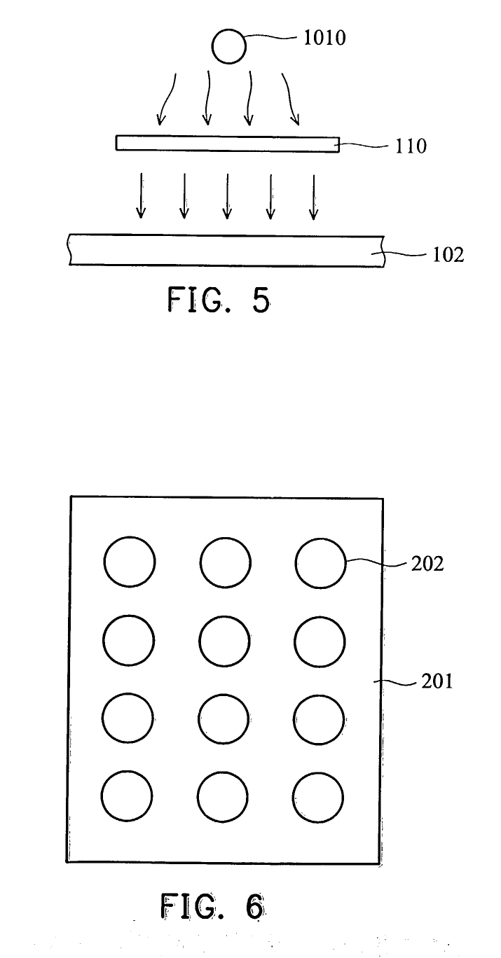

Then, an exposure is performed by transmitting a light source 1010, such as deep ultraviolet (UV), extreme ultraviolet, or X-ray, through the mask 110, as shown in FIG. 5. High degree diffraction waves, from light entering the contact hole transparent areas 120, can be eliminated by the 0° phase opening. Then, the pattern with contact hole transparent areas 120 is transferred to the photoresist layer 102.

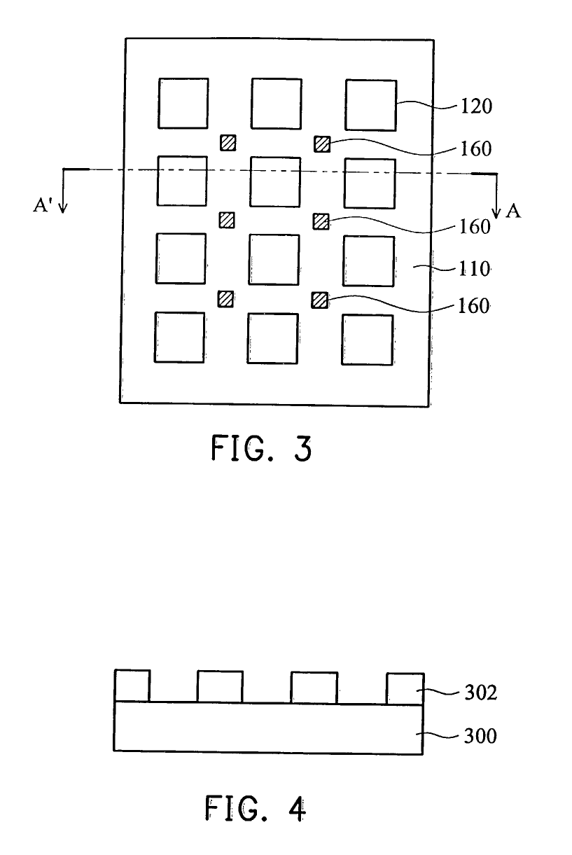

In order to clarify the structure of the mask according to the present invention, the top view schematic drawing and the cross-section drawing of the mask are presented, as shown in FIG. 3 and FIG. 4. The mask 110 comprises a transparent substrate 300, a 180° phase shift layer 302 installed on the transparent substrate 300 to define a series of patterns having contact hole transparent areas 120 with 0° phase, and at least one 0° phase opening 160 installed in the phase shift layer 302 between the adjacent contact hole transparent areas 120. The contact hole transparent areas 120 are set in array, and each of the contact hole transparent areas can be about 100˜300 nm. As well, the pitch between the contact hole transparent areas is about 300˜600 nm. The transparent substrate comprises quartz, and the phase shift layer comprises MoSiON.

After exposure, the patterns transferred on the photoresist layer 102 are shown in FIG. 6. Under this method no side lobes occur.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. An exposure method of a contact hole, comprising:
providing a mask including a transparent substrate, a 180° phase shift layer installed on the transparent substrate to define a series of patterns having contact hole transparent areas with 0° phase, and at least one 0° phase opening installed in the phase shift layer between the adjacent contact hole transparent areas; and
performing an exposure by transmitting a light source through the mask, so as to eliminate high degree diffraction waves by the 0° phase opening.

2. The method as claimed in claim 1, wherein the light is deep ultraviolet (UV), extreme ultraviolet, or X-ray.

3. The method as claimed in claim 1, wherein each of the contact hole transparent areas is rectangular.

4. The method as claimed in claim 1, wherein each of the contact hole transparent areas is about 100˜300 nm.

5. The method as claimed in claim 1, wherein the contact hole transparent areas are set in array.

6. The method as claimed in claim, 5, wherein the pitch between the contact hole transparent areas is about 300˜600 nm.

7. The method as claimed in claim 1, wherein the 0° opening is installed at the convergence of four adjacent contact hole transparent areas.

8. The method as claimed in claim 1 wherein the 0° opening is rectangular.

9. The method as claimed in claim 1 wherein the phase shift layer comprises MoSiON.

10. A mask for contact hole exposure, comprising:
a transparent substrate;
a 180° phase shift layer installed on the transparent substrate to define a series of patterns having contact hole transparent areas with 0° phase; and
at least one 0° phase opening installed in the phase shift layer between the adjacent contact hole transparent areas to eliminate high degree diffraction waves.

11. The mask as claimed in claim 10, wherein the transparent substrate comprises quartz.

12. The mask as claimed in claim 10, wherein the phase shift layer comprises MoSiON.

13. The mask as claimed in claim 10, wherein the light is deep ultraviolet (UV), extreme ultraviolet, or X-ray.

14. The mask as claimed in claim 10, wherein each of the contact hole transparent areas is rectangular.

15. The mask as claimed in claim 10, wherein each of the contact hole transparent areas is about 100˜300 nm.

16. The mask as claimed in claim 10, wherein the contact hole transparent areas are set in array.

17. The mask as claimed in claim 16, wherein the pitch between the contact hole transparent areas is about 300˜600 nm.

18. The mask as claimed in claim 16, wherein the 0° opening is installed at the convergence of four adjacent contact hole transparent areas.

19. The mask as claimed in claim 9, wherein the 0° opening is rectangular.
